(19) United States
(12) Patent Application Publication
(10) Pub. No.: US 2024/0222323 A1
(43) Pub. Date: Jul. 4, 2024

(54) FAN-OUT STACKED PACKAGE, METHOD OF MAKING AND ELECTRONIC DEVICE INCLUDING THE STACKED PACKAGE

(71) Applicant: Yibu Semiconductor Co., Ltd., Shanghai (CN)

(72) Inventor: Ming Li, Fremont, CA (US)

(73) Assignee: Yibu Semiconductor Co., Ltd., Shanghai (CN)

(21) Appl. No.: 18/401,329

(22) Filed: Dec. 29, 2023

(30) Foreign Application Priority Data
Dec. 29, 2022 (CN) 202211707002.5
Dec. 29, 2022 (CN) 202211707058.0

(51) Int. Cl. H01L 25/065; H01L 23/00; H01L 23/528; H01L 25/00

(52) U.S. Cl. CPC H01L 25/0652; H01L 23/528; H01L 24/16; H01L 25/50; H01L 2224/16145

(57) ABSTRACT

The present disclosure relates to a fan-out stack package, a method and apparatus for manufacturing the same, the fan-out stack package comprising: at least two pre-packages; each pre-package comprises at least a chip, a first redistribution layer and a first connector; the pre-packages are stacked and interconnected, and a first connector of one pre-package of two adjacent pre-packages is electrically connected with a first redistribution layer of the other pre-package; the first redistribution layer is positioned on one side of the active surface of the chip, and the first connecting body and the chip are positioned on the same side of the first redistribution layer; in a first preset direction, at least some of the first connectors are positioned on at least one edge side of the chip; the pre-package comprises a first pre-package and at least one second pre-package; the first pre-package is positioned at the outermost side of the fan-out type stacked package; in the first preset direction, the length of the first pre-package is greater than that of the second pre-package. Therefore, the length of the electric interconnection is shortened, the electric performance is higher, and the perforation and the connection of the substrate are not needed, thereby being beneficial to reducing the cost.

### CROSS REFERENCE TO RELATED APPLICATION

The present application claims the benefit of priority under the Paris Convention to Chinese Patent Application No. 202211707002.5A, filed on Dec. 29, 2022, Chinese Patent Application No. 202211707058.0A, filed on Dec. 29, 2022, each of which is incorporated herein by reference in its entirety. The present application is related to co-pending US patent application entitled “Stacked package, method of making and electronic device including the stacked package,” filed on even date herewith, which is incorporated herein by reference in its entirety.

### FIELD

The present disclosure relates to the field of semiconductor technology, and in particular, to a fan-out stacked package, a method of making and an electronic device including the same.

### BACKGROUND

In the field of logic and memory integration, package-on-package (Package on Package, PoP) has become the first choice in the industry, mainly for manufacturing advanced mobile communication platforms for high-end portable devices and smart phones. The low power memory package is formed by stacking a plurality of memory chips, and is mainly applied to the upper layer of a package stack in a smart phone or directly soldered on a motherboard of a portable computer by Wire Bonding (WB) as interconnection.

In the related art, the low-power memory storage technology is a fifth generation low-power dual data rate memory standard (Low Power Double Data Rate x, lpddr5 x), and the maximum memory speed is 8.5 Gbps; future sixth generation low Power dual data rate memory standards (Low Power Double Data Rate x, lpddr6 x) predict a maximum memory speed of 17.0 Gbps, at this 17.0 Gbps memory high speed operation speed, wire Bonding (WB) is not sustainable as an interconnection of memory stacks due to Signal Integrity (SI) and Power Integrity (PI) considerations, and due to longer metal Wire and small diameter, its impedance is also higher, resulting in poor electrical performance, easy Signal distortion and long transmission time; the Through-Silicon-Via (TSV) technology reduces the interconnection length Through vertical interconnection, reduces signal delay, has good electrical performance, reduces capacitance/inductance, realizes low-power consumption and high-speed communication between chips, has higher space efficiency and higher interconnection density, and has higher process cost.

In the field of computer servers as well, with the increase of computing power, the demand for memory capacity is also increasing, and fourth/fifth generation double data rate synchronous dynamic random access memory (Double Data Rate Fourth/Fifth Generation Synchronous Dynamic Random Access Memory, DDR4/5 SDRAM) stacking is a path for solving the demand for memory capacity, and two schemes exist: the DDR4/5 memory package is formed by stacking a plurality of memory chips and is interconnected through wire bonding; secondly, DDR4/5 memory packages are stacked with multiple memory chips, interconnected by through silicon via technology. Both of these solutions have the same technical problems as described above, namely, wire bonding has poor electrical properties and through silicon vias have the technical problem of high process cost.

### SUMMARY

In order to solve the technical problems described above or at least partially solve the technical problems described above, the present disclosure provides a fan-out type stack package, a method and an apparatus for manufacturing the same.

In a first aspect, the present disclosure provides a fan-out stack package, comprising: at least two pre-packages; each pre-package comprises at least a chip, a first redistribution layer and a first connector.

The at least two pre-packages are in stacked interconnection, the active surface of one pre-package body in two adjacent pre-packages is opposite to the passive surface of the other pre-package body, and the first connecting body of one pre-package body is electrically connected with the first redistribution layer of the other pre-package body.

In some embodiments, in the stacking interconnection direction, the first redistribution layer is positioned on one side of the active surface of the chip, and the first connector and the chip are positioned on the same side of the first redistribution layer; in a first preset direction, at least some of the first connectors are positioned on at least one edge side of the chip, and the first connector is electrically connected with the chip through the first redistribution layer.

The pre-package comprises a first pre-package and at least one second pre-package; the first pre-package body is positioned at the outermost side of the fan-out type stacked package body and is used for being electrically connected with other components; in a first preset direction, the length of the first pre-package is greater than that of the second pre-package, and the first preset direction is any direction perpendicular to the stacking interconnection direction.

In some embodiments, the pre-package further comprises: a pre-encapsulation layer, wherein the pre-encapsulation layer encapsulates the chip and the first connector; the first connector comprises a first conductor post;

The first conductor column is filled and penetrates through the pre-encapsulation layer and is connected with a first redistribution layer of the pre-packaging body.

In some embodiments the first connector of the second pre-package further comprises a metal bump; the metal bump is electrically connected with the first conductor post and is exposed outside the surface of the pre-encapsulation layer; the metal bump is electrically connected with the first redistribution layer of the adjacent pre-package.

In some embodiments, the first pre-package further comprises a second redistribution layer and a second connector; the second redistribution layer is located the chip with the first conductor post deviates from one side of first redistribution layer, the second connector is located the second redistribution layer deviates from the chip with one side of first conductor post, the second redistribution layer with first conductor post with the second connector electricity is connected, the second connector is used for external connection other components and parts.

In some embodiments, the second connector is provided as at least one of a second conductor post and a solder ball.

In some embodiments, the fan-out stack package further comprises: the encapsulation layer is formed by a encapsulation layer, the encapsulation layer is positioned on one side of the first pre-packaging body facing the second pre-packaging body, and the encapsulation layer coats the surface of the first pre-packaging body facing the second pre-packaging body and the second pre-packaging body.

In some embodiments, the pre-package further comprises: a bond pad; the bonding pads are located on one side of the active surface of the chip, the bonding pads are distributed in the area, close to the first connecting body, of the chip, and the bonding pads are electrically connected with the first connecting body through the first redistribution layer.

In some embodiments, the chip includes at least one of a memory chip, a computing chip, a communication chip, a sensing chip, and an energy chip.

In some embodiments, the first connectors in two adjacent pre-packages are arranged at the same position.

In a second aspect, the present disclosure further provides a method for preparing a fan-out stack package, including:
forming at least two pre-packages; the pre-package body comprises a chip, a first redistribution layer and a first connecting body; and
interconnecting the pre-packages in a stacked manner, wherein the active surface of one pre-package body of two adjacent pre-packages is opposite to the passive surface of the other pre-package body, and the first connecting body of one pre-package body is electrically connected with the first redistribution layer of the other pre-package body;
wherein, in the stacking interconnection direction, the first redistribution layer is positioned on one side of the active surface of the chip, and the first connector and the chip are positioned on the same side of the first redistribution layer; in a first preset direction, at least some of the first connectors are positioned on at least one edge side of the chip, and the first connector is electrically connected with the chip through the first redistribution layer.

The pre-package comprises a first pre-package and at least one second pre-package; the first pre-package body is positioned at the outermost side of the fan-out type stacked package body and is used for being electrically connected with other components; in a first preset direction, the length of the first pre-package is greater than that of the second pre-package, and the first preset direction is any direction perpendicular to the stacking interconnection direction.

In some embodiments, forming the pre-package includes:
providing a first carrier plate;
forming a first conductor column on one side of the first carrier plate;
providing at least one chip;
attaching the active surface of the chip to the first carrier plate; the chip and the first conductor post are positioned on the same side of the first carrier plate;
forming a pre-encapsulation layer, wherein the pre-encapsulation layer coats the surfaces of the chip, the first conductor column and the first carrier plate, which face the chip and the first conductor column, and the first conductor column is filled and penetrates through the pre-encapsulation layer;
providing a second carrier plate and attaching the second carrier plate to one side of the pre-encapsulation layer, which is away from the first carrier plate;
and removing the first carrier plate, and forming a first redistribution layer on one side of the chip and the first conductor column, which is away from the second carrier plate, wherein the first redistribution layer is electrically connected with the chip and the first conductor column.

In some embodiments, forming the second pre-package further includes:
providing a third carrier plate and attaching the third carrier plate to one side of the first redistribution layer, which is away from the chip and the first conductor column;
and removing the second carrier plate, and forming a metal bump on one side of the first conductor column, which is away from the third carrier plate, wherein the metal bump is electrically connected with the first conductor column and is exposed outside the surface of the pre-encapsulation layer.

In some embodiments, after the interconnecting the pre-package stack, the method of preparing further comprises:
forming a encapsulation layer on one side of the first pre-packaging body facing the second pre-packaging body; the encapsulation layer coats the surface of the first pre-packaging body facing the second pre-packaging body.

In some embodiments, the preparation method further comprises:
removing a second carrier plate on one side of the first pre-package body away from the second pre-package body;
forming a second redistribution layer on one side of the chip and the first conductor pillar away from the first redistribution layer;
forming a second connector on one side of the second redistribution layer away from the chip and the first conductor pillar;
the second redistribution layer is electrically connected with the first connector and the second connector, and the second connector is used for externally connecting other components.

In a third aspect, the present disclosure also provides an electronic device, including: any of the fan-out stack packages described above.

Compared with the prior art, the technical scheme provided by the disclosure has the following advantages:
the disclosure provides a fan-out type stack package, a method and an apparatus for manufacturing the same, the fan-out type stack package comprising: at least two pre-packages; each pre-package comprises a chip, a first redistribution layer and a first connector; the active surface of one of the two adjacent pre-packages is opposite to the passive surface of the other pre-package, and the first connector of one pre-package is electrically connected with the first redistribution layer of the other pre-package; wherein, in the stacking interconnection direction, the first redistribution layer is positioned on the active surface side of the chip, and the first connecting body and the chip are positioned on the same side of the first redistribution layer; in a first preset direction, at least some of the first connectors are positioned on at least one edge side of the chip, and the first connector is electrically connected with the chip through the first redistribution layer; the pre-package comprises a first pre-package and at least one second pre-package; the first pre-package is positioned at the outermost side of the fan-out type stacked package and is used for being electrically connected with other components; in a first preset direction, the length of the first pre-package is greater than that of the second pre-package, and the first preset direction is any direction perpendicular to the stacked interconnection direction. Therefore, the stacked interconnection of the chip is realized through the first connector and the first redistribution layer, the length of the electric interconnection is shortened, the electric performance is higher, the connection reliability and the signal transmission speed are improved, and the perforation and the connection substrate are not needed, so that the cost is reduced.

### BRIEF DESCRIPTION OF THE DRAWINGS

The accompanying drawings, which are incorporated in and constitute a part of this specification, illustrate embodiments consistent with the disclosure and together with the description, serve to explain the principles of the disclosure.

In order to more clearly illustrate the embodiments of the present disclosure or the solutions in the prior art, the drawings that are required for the description of the embodiments or the prior art will be briefly described below, and it will be obvious to those skilled in the art that other drawings can be obtained from these drawings without inventive effort.

FIG. 1 is a schematic structural diagram of a fan-out stack package according to an embodiment of the disclosure;

FIG. 2 is a schematic diagram of another fan-out stack package according to an embodiment of the disclosure;

FIG. 3 is a schematic structural diagram of a second pre-package according to an embodiment of the disclosure;

FIG. 4 is a schematic structural diagram of a first pre-package according to an embodiment of the disclosure;

FIG. 5 is a schematic diagram of another second pre-package according to an embodiment of the disclosure;

FIG. 6 is a schematic structural view of yet another second pre-package provided in an embodiment of the present disclosure;

FIG. 7 is a schematic diagram of a second pre-package according to an embodiment of the present disclosure;

FIG. 8 is a schematic structural view of another first pre-package according to an embodiment of the disclosure;

FIG. 9 is a schematic diagram of a second pre-package according to an embodiment of the present disclosure;

FIG. 10 is a schematic diagram of a second pre-package according to an embodiment of the present disclosure;

FIG. 11 is a schematic structural view of yet another second pre-package provided in an embodiment of the present disclosure;

FIG. 12 is a schematic diagram of a second pre-package according to an embodiment of the present disclosure;

FIG. 13 is a schematic flow chart of a method for manufacturing a fan-out stack package according to an embodiment of the disclosure;

FIG. 14 is a schematic diagram of a refinement flow for forming a pre-package according to an embodiment of the disclosure;

FIG. 15 is a schematic diagram showing the structure of the pre-package;

FIG. 16 is a schematic illustration of a refinement flow for forming a second pre-package according to an embodiment of the disclosure;

FIG. 17 is a schematic diagram showing the structure of the second pre-package according to the steps of forming the second pre-package;

FIG. 18 is a flowchart illustrating a method for manufacturing a fan-out stack package according to another embodiment of the disclosure;

FIG. 19 is a schematic structural diagram corresponding to S403 to S406 in the method for manufacturing the fan-out stack package shown in FIG. 18.

### DETAILED DESCRIPTION OF THE EMBODIMENTS

In order that the above objects, features and advantages of the present disclosure may be more clearly understood, a further description of aspects of the present disclosure will be provided below. It should be noted that, without conflict, the embodiments of the present disclosure and features in the embodiments may be combined with each other.

In the following description, numerous specific details are set forth in order to provide a thorough understanding of the present disclosure, but the present disclosure may be practiced otherwise than as described herein; it will be apparent that the embodiments in the specification are only some, but not all, embodiments of the disclosure.

In view of the problems set forth in the background section, embodiments of the present disclosure provide a fan-out stack package, a method and apparatus for manufacturing the same, the fan-out stack package including: at least two pre-packages; each pre-package comprises a chip, a first redistribution layer and a first connector; the active surface of one of the two adjacent pre-packages is opposite to the passive surface of the other pre-package, and the first connector of one pre-package is electrically connected with the first redistribution layer of the other pre-package; wherein, in the stacking interconnection direction, the first redistribution layer is positioned on the active surface side of the chip, and the first connecting body and the chip are positioned on the same side of the first redistribution layer; in a first preset direction, at least some of the first connectors are positioned on at least one edge side of the chip, and the first connector is electrically connected with the chip through the first redistribution layer; the pre-package comprises a first pre-package and at least one second pre-package; the first pre-package is positioned at the outermost side of the fan-out type stacked package and is used for being electrically connected with other components; in a first preset direction, the length of the first pre-package is greater than that of the second pre-package, and the first preset direction is any direction perpendicular to the stacked interconnection direction. Therefore, the stacked interconnection of the chip is realized through the first connector and the first redistribution layer, the length of the electric interconnection is shortened, the electric performance is higher, the connection reliability and the signal transmission speed are improved, and the perforation and the connection substrate are not needed, so that the cost is reduced.

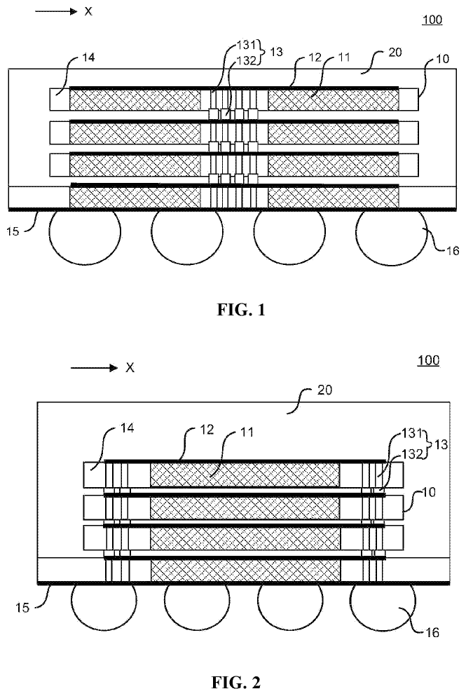

Exemplary descriptions of fan-out stack packages, methods of making the same, and apparatus provided in embodiments of the present disclosure are provided below in connection with FIGS. 1-19.

The embodiment of the disclosure provides a stacked package, as shown in FIGS. 1-2, FIG. 1 is a schematic structural diagram of a stacked package provided in the embodiment of the disclosure, and FIG. 2 is a schematic structural diagram of another stacked package provided in the embodiment of the disclosure. Referring to FIGS. 1-2, the fan-out stack package 100 includes: at least two pre-packages 10; each pre-package 10 includes at least a chip 11, a first redistribution layer 12, and a first connection 13; at least two pre-packages 10 are stacked and interconnected, the active surface of one pre-package 10 of the adjacent two pre-packages 10 is opposite to the passive surface of the other pre-package 10, and the first connection body 13 of one pre-package 10 is electrically connected with the first redistribution layer 12 of the other pre-package 10; wherein, in the stacking interconnection direction, the first rerouting layer 12 is located at the active surface side of the chip 11, and the first connector 13 and the chip 11 are located at the same side of the first rerouting layer 12; in the first preset direction X, the first connecting body 13 is located on at least one edge side of the chip 11, and the first connecting body 13 is electrically connected with the chip 11 through the first redistribution layer 12; the pre-package 10 comprises a first pre-package and at least one second pre-package; the first pre-package is positioned at the outermost side of the fan-out type stacked package and is used for being electrically connected with other components; in a first preset direction X, the length of the first pre-package is greater than the length of the second pre-package, and the first preset direction X is any direction perpendicular to the stacking interconnection direction.

The chip 11 includes, but is not limited to, a memory chip, a computing chip, a sense chip, a communication chip, a sense chip, and an energy chip, for example, a dynamic random access memory (Dynamic Random Access Memory, DRAM) chip or a double rate dynamic random access memory (Double Data Rate Dynamic Random Access Memory, DDR DRAM).

The first redistribution layer 12 is a metal thin film layer and may be prepared by electroplating or deposition processes; the metal material can be at least one of copper, aluminum, silver, gold and titanium. The first connecting body 13 has a height in the stacked interconnection direction equal to or greater than the height of the chip 11, and is arranged such that the first connecting body 13 of the pre-package 10 located at the upper layer can be in contact with the first redistribution layer 12 of the pre-package 10 located at the lower layer, ensuring reliable connection. The first connecting body 13 may be provided with a metal column or a metal block formed of a metal material, such as a copper column, an aluminum column, a silver column, or the like, or may be a column formed of another conductive material, which is not limited herein. The first connector 13 and the first redistribution layer 12 may be made of the same material, or may be made of different materials, which is not limited herein.

Wherein the first pre-package is the one at the bottom layer in the fan-out stack package 100, and the remaining other pre-packages are the second pre-packages; as shown in FIG. 1-2, the first preset direction X is perpendicular to the stacking interconnection direction, and the length of the first pre-package is greater than that of the second pre-package; when the fan-out type stacked packaging body is integrally packaged, one side, facing the second pre-packaging body, of the first pre-packaging body can be used as a substrate, and a supporting effect is provided for the encapsulation layer without connecting a substrate. The fan-out stack package 100 may be electrically connected to other components by forming the second redistribution layer 15 and the second connection body 13 on a side of the first pre-package facing away from the second pre-package.

Illustratively, as shown in FIG. 1, the fan-out stack package 100 includes four stacked interconnected pre-packages 10, wherein one pre-package 10 located at the bottom layer of the fan-out stack package 100 is a first pre-package, and the remaining other pre-packages 10 are second pre-packages; each pre-package 10 includes two chips 11, a first re-wiring layer 12, and a first connection body 13; in the stacking interconnection direction, the active surface of the chip 11 is electrically connected with the first redistribution layer 12, and in the first preset direction X, the first connecting body 13 is located at one edge side of the chip 11, and the first connecting body 13 is electrically connected with the chip 11 through the first redistribution layer 12; the first connecting bodies 13 are distributed in the region between the two chips 11. In the stacking interconnection direction, the first connecting body 13 of the pre-package 10 located at the upper layer of the two adjacent pre-packages 10 is electrically connected with the first re-wiring layer 12 of the pre-package 10 located at the lower layer thereof, one side of the chip 11 of the pre-package 10 facing the first re-wiring layer 12 is an active surface, and one side facing away from the re-wiring layer is a passive surface, so that the passive surface of the pre-package 10 located at the upper layer is opposite to the active surface of the pre-package 10 located at the lower layer; the stacked interconnection of the chip is realized through the first connecting body 13 and the first redistribution layer 12, so that the length of the electric interconnection is shortened; in the first preset direction X, the length of the first pre-package is greater than that of the second pre-package, and the first pre-package can be used as a substrate, and a package layer is formed on one side of the first pre-package facing the second pre-package, so that a connection substrate is not required, and cost reduction is facilitated.

Illustratively, as shown in FIG. 2, the fan-out stack package 100 includes four stacked interconnected pre-packages 10, wherein one pre-package 10 located at the bottom layer of the fan-out stack package 100 is a first pre-package, and the remaining other pre-packages 10 are second pre-packages; each pre-package 10 includes one chip 11, a first re-wiring layer 12, and a first connection body 13; in the stacking interconnection direction, the active surface of the chip 11 is electrically connected with the first redistribution layer 12, and in the first preset direction X, the first connecting bodies 13 are positioned at two sides of the chip 11, and the first connecting bodies 13 are electrically connected with the chip 11 through the first redistribution layer 12; the first connecting bodies 13 are distributed in both side regions of the chip 11. In the stacking interconnection direction, the first connector 13 of the pre-package 10 located at the upper layer of the two adjacent pre-packages 10 is electrically connected with the first re-wiring layer 12 of the pre-package 10 located at the lower layer, one side of the chip 11 of the pre-package 10 facing the first re-wiring layer 12 is an active surface, and one side facing away from the re-wiring layer is a passive surface, so that the passive surface of the pre-package 10 located at the upper layer is opposite to the active surface of the pre-package 10 located at the lower layer; the stacked interconnection of the chip is realized through the first connecting body 13 and the first redistribution layer 12, so that the length of the electric interconnection is shortened; in the first preset direction X, the length of the first pre-package is greater than that of the second pre-package, and the first pre-package can be used as a substrate, and a package layer is formed on one side of the first pre-package facing the second pre-package, so that a connection substrate is not required, and cost reduction is facilitated.

The first connection body 13 of the pre-package body 10 located at the upper layer is electrically connected to the first redistribution layer 12 of the pre-package body 10 located at the lower layer thereof, and may be connected by using any metal connection process known to those skilled in the art, such as pressure welding, arc welding, argon arc welding, gas shielded arc welding, and laser welding, which are not limited herein.

It should be noted that FIG. 1-2 only exemplarily show that the stack package 100 includes four pre-packages 10, and each pre-package 10 in FIG. 1 includes two chips 11 and the first connection body 13 is distributed in a region between the two chips 11; each pre-package 10 in FIG. 2 includes a chip 11 and first connectors 13 distributed on both sides of the chip 11, but none of the above constitutes a limitation of the stack package provided in the embodiments of the present disclosure. In other embodiments, the number of the pre-packages 10, the number of the chips 11 in each pre-package 10, and the distribution area of the first connection bodies 13 may be set according to the requirements of the stack package, which is not limited herein.

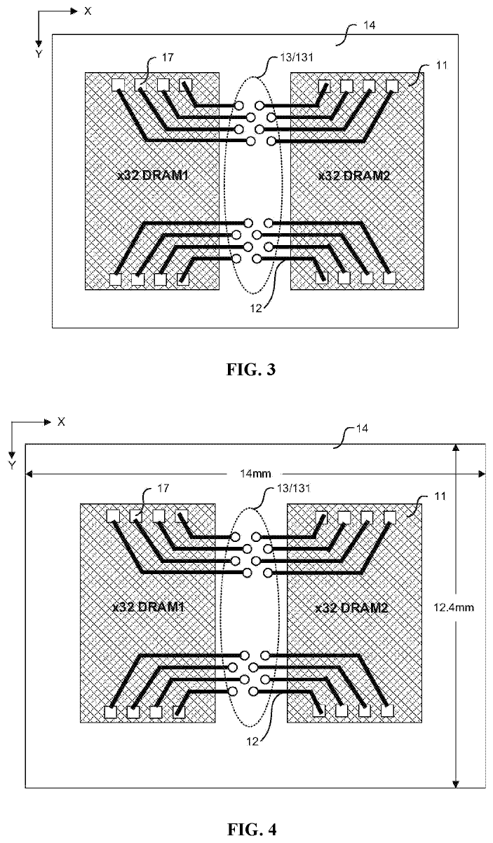

3-4, FIG. 3 is a schematic structural diagram of a second pre-package provided in an embodiment of the disclosure, and FIG. 4 is a schematic structural diagram of a first pre-package provided in an embodiment of the disclosure; wherein, the first preset direction X and the second preset direction Y are perpendicular to the stacking interconnection direction. Referring to FIGS. 3 to 4, in the first preset direction X and the second preset direction Y, the length of the first pre-package is greater than the length of the second pre-package; when the fan-out type stacked packaging body is integrally packaged, one side, facing the second pre-packaging body, of the first pre-packaging body can be used as a substrate, and a supporting effect is provided for the encapsulation layer without connecting a substrate. The length of the first pre-package is equal to the length of the package layer in either direction perpendicular to the stack interconnect; for example, the length of the first pre-package in the first preset direction X is 14 mm and the length in the second preset direction Y is 12.4 mm.

It can be appreciated that FIG. 4 illustrates the first pre-package size of 14 mm×12.4 mm by way of example only, and is not limiting of the embodiments of the present disclosure. In other embodiments, the first pre-package layer is sized according to the requirements of the removable stack package, for example, the first pre-package is sized 7.5 mm by 11 mm for a single DDR4 DRAM chip and the first pre-package is sized 9 mm by 11 mm for a single DDR5 DRAM chip, which is not limited herein.

The disclosed embodiments provide a fan-out stack package 100, comprising: at least two pre-packages 10; each pre-package 10 includes a chip 11, a first redistribution layer 12, and a first connection 13; the pre-packages 10 are interconnected in a stacked manner, the active surface of one pre-package 10 of two adjacent pre-packages 10 is opposite to the passive surface of the other pre-package 10, and the first connecting body 13 of one pre-package 10 is electrically connected with the first redistribution layer 12 of the other pre-package 10; wherein, in the stacking interconnection direction, the first rerouting layer 12 is located at the active surface side of the chip 11, and the first connector 13 and the chip 11 are located at the same side of the first rerouting layer 12; in the first preset direction, the first connector 13 is located on at least one edge side of the chip 11, and the first connector 13 is electrically connected with the chip 11 through the first redistribution layer 12; the pre-package 10 comprises a first pre-package and at least one second pre-package; the first pre-package is positioned at the outermost side of the fan-out type stacked package and is used for being electrically connected with other components; in a first preset direction X, the length of the first pre-package is greater than the length of the second pre-package, and the first preset direction X is any direction perpendicular to the stacking interconnection direction. Thus, the stacked interconnection of the chips is realized by the first connecting body 13 and the first redistribution layer 12, the length of the electrical interconnection is shortened, the electrical performance is higher, the connection reliability and the signal transmission speed are improved, and the perforation and the connection substrate are not needed, so that the cost is reduced.

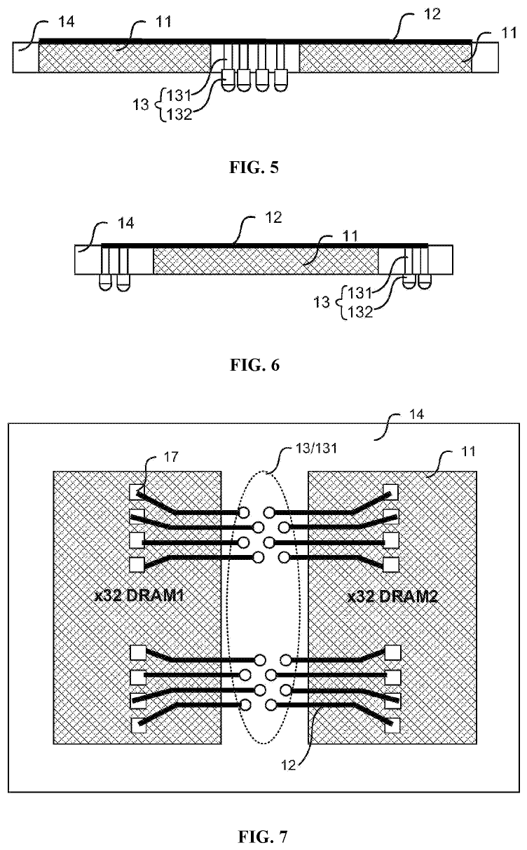

In some embodiments, as shown in FIG. 1-2 and FIG. 5-6, FIG. 5 is a schematic structural diagram of another second pre-package provided in an embodiment of the disclosure, and FIG. 6 is a schematic structural diagram of yet another second pre-package provided in an embodiment of the disclosure. Referring to FIGS. 1-2 and 5-6, the pre-package further includes: a pre-encapsulation layer 14, the pre-encapsulation layer 14 encapsulating the chip 11 and the first connection body 13; the first connecting body 13 includes a first conductor pillar 131; the first conductor pillars 131 fill and penetrate the pre-package layer 14, connecting the first redistribution layer 12 of the pre-package.

Wherein the pre-encapsulation layer 14 may be provided as a resin layer, the material may be one or more combinations of epoxy (Epoxy Molding Compound, EMC), polyethylene, polypropylene, polyolefin, polyamide, polyurethane, etc. The pre-encapsulation layer 14 encapsulates the chip 11 and the first connection body 13 and the surfaces of the first re-wiring layer 12 facing the chip 11 and the first connection body 13, and fills the gap between the chip 11 and the first connection body 13; the surface of the first redistribution layer 12 facing away from the chip 11 and the first connection body 13 is exposed at the surface of the pre-encapsulation layer 14, and the surface of the first redistribution layer 12 facing away from the chip 11 and the first connection body 13 may be flush or convex with the surface of the pre-encapsulation layer 14.

The first conductor pillar 131 of the first connector 13 is located in the pre-package layer 14 and penetrates through the pre-package layer 14, and one end of the first conductor pillar 131 is connected with the first redistribution layer of the pre-package.

In some embodiments, as shown in FIG. 5-6, the first connecting body 13 of the second pre-package further comprises a metal bump 132; the metal bump 132 is electrically connected with the first conductor pillar 131 and is exposed outside the surface of the pre-encapsulation layer 14; the metal bump 132 is electrically connected to the first redistribution layer 12 of an adjacent pre-package.

The metal bump 132 is electrically connected to one end of the first conductor pillar 131 facing away from the first redistribution layer 12, and protrudes from a surface of the pre-package layer 14 facing away from the first redistribution layer 12, and is electrically connected to the first redistribution layer 12 of the adjacent pre-package body 10. The first conductor pillar 131 and the metal bump 132 may be made of the same metal material, or may be made of different metal materials, which is not limited herein.

1-2, the second pre-package is applicable to the 1 st to 3 rd pre-packages, i.e., the pre-packages other than the bottommost pre-package in the fan-out stack package, in a top-down order; in the first preset direction X, the length of the metal bump 132 is greater than the length of the first conductor pillar 131, so that the contact area between the metal bump 132 and the first redistribution layer 12 of the adjacent pre-package is increased, the connection reliability is improved, and the connection process difficulty is reduced; the first preset direction X is any direction perpendicular to the stacking interconnection direction.

In some embodiments, the first connecting body 13 further includes a solder bump at an end of the metal bump 132 facing away from the first conductor pillar 131, and is a cap bump, and the solder bump is made of a conductive metal, such as tin.

In some embodiments, as shown in FIG. 1-2, the first pre-package further includes a second redistribution layer 15 and a second connector 16; the second redistribution layer 15 is located on a side of the chip 11 and the first conductor pillar 131 away from the first redistribution layer 12, the second connector 16 is located on a side of the second redistribution layer 15 away from the chip 11 and the first conductor pillar 131, the second redistribution layer 15 is electrically connected with the first conductor pillar 131 and the second connector 16, and the second connector 16 is used for externally connecting other components.

The first pre-package is a pre-package 10 located at the bottommost part of the fan-out type stack package in the stack interconnection direction, and the rest of the other pre-packages 10 are second pre-packages, wherein the second pre-packages are all stacked above the first pre-package; the side of the first pre-package facing away from the second pre-package is sequentially provided with a second redistribution layer 15 and a second connector 16, and the second connector 16 is used for externally connecting other components, such as a substrate, a printed circuit board (Printed Circuit Boards, PCB) or a processor, which may be a central processing unit (Central Processing Unit, CPU) or other form of processing unit having data processing capability and/or instruction execution capability.

Since the bottom of the first pre-package is no longer stacked to connect with other pre-packages 10, the first connector 13 of the first pre-package only includes the first conductor pillar 131 penetrating through the pre-package layer 14, and no metal bump 132 is provided; a second redistribution layer 15 is formed on a side of the first pre-package facing away from the first redistribution layer 12, the first connection body 13 is electrically connected to the second redistribution layer 15, the second redistribution layer 15 is electrically connected to the second connection body 16, and interconnection between all pre-packages 10 in the stacked package 100 and a base (such as a substrate, PCB, or CPU) is achieved through the first connection body 13, the second redistribution layer 15, and the second connection body 16.

The second redistribution layer 15 is a metal thin film layer and may be prepared by using an electroplating or deposition process; the metal material can be at least one of copper, aluminum, silver, gold and titanium.

The second connector 16 is configured in a column, block or sphere shape and is made of a conductive material including a metallic material (e.g., at least one of copper, aluminum, silver, gold, and titanium) and a conductive nonmetallic material. The number and arrangement of the second connectors 16 are flexibly set according to the external connection components, which is not limited herein.

In some embodiments, the second connector is provided as at least one of a second conductor post and a solder ball.

Illustratively, as shown in FIG. 1, the second connecting bodies 13 are provided as solder balls with a solder ball pitch of 0.4 mm; the actual number of solder balls is 496.

Illustratively, as shown in FIG. 2, the second connector is provided as solder balls with a solder ball pitch of 0.8 mm; for DDR4 DRAM chips, the actual number of solder balls is 78; for DDR5 DRAM chips, the actual number of solder balls is 82.

It will be appreciated that FIG. 1-2 only exemplarily illustrate that the second connection body 16 is provided as a solder ball, but do not constitute a limitation of the fan-out stack package provided by the embodiments of the present disclosure. In other embodiments, the second connector 16 may be provided in other forms known to those skilled in the art, such as in a column or block shape; the number of the second connectors is also set according to the requirements of the out-type stacked package, which is not limited herein.

In some embodiments, as shown in FIG. 1-2, the fan-out stack package 100 further comprises: the encapsulation layer 20 is positioned on one side of the first pre-packaging body facing the second pre-packaging body, and the encapsulation layer 20 coats the surface of the first pre-packaging body facing the second pre-packaging body and the second pre-packaging body.

The encapsulation layer 20 may be a prepreg, and the surface of the second pre-encapsulation body and the surface of the first pre-encapsulation body facing the second pre-encapsulation body are coated with the prepreg, where the prepreg includes one or more of epoxy resin, polyethylene, polypropylene, polyolefin, polyamide, polyurethane, and the like. The encapsulation layer 20 may be made of a liquid or powder epoxy resin, and not only encapsulates the second pre-encapsulation body and the surface of the first pre-encapsulation body facing the second pre-encapsulation body, but also fills the gaps between all the pre-encapsulation bodies.

In this way, the fan-out stack package 100 is protected from damage caused by external factors (such as liquid and metal), and meanwhile, all the pre-packages are fixed, so that the connection circuit is prevented from being disconnected due to movement of the pre-packages.

In some embodiments, as shown in FIG. 7-11, the pre-package further comprises: a bond pad 17; the bonding pads 17 are located on the active surface side of the chip 11, the bonding pads 17 are distributed in a region of the chip 11 close to the first connection body 13, and the bonding pads 17 are electrically connected to the first connection body 13 through the first redistribution layer 12.

The bond pads 17 of the prior art are typically located at the edge of the chip 11 (as shown in FIG. 3 or 4), which, if applied to the present disclosure, shortens the vertical interconnect length between the pre-package layers; however, since the arrangement direction of the bonding pads 17 is perpendicular to the overall arrangement direction of the first connection body 13, there is a problem that the length of the first redistribution layer 12 is long, and the scheme can be further optimized by adjusting the distribution position of the bonding pads 17. According to the embodiment of the disclosure, the distribution positions of the bonding pads 17 are set according to the distribution positions of the first connectors 13, so that the bonding pads 17 are distributed in the area of the chip 11 close to the first connectors 13, so as to shorten the length of the first redistribution layer 12, i.e. shorten the electrical interconnection length, reduce the capacitance and inductance, and further improve the electrical performance.

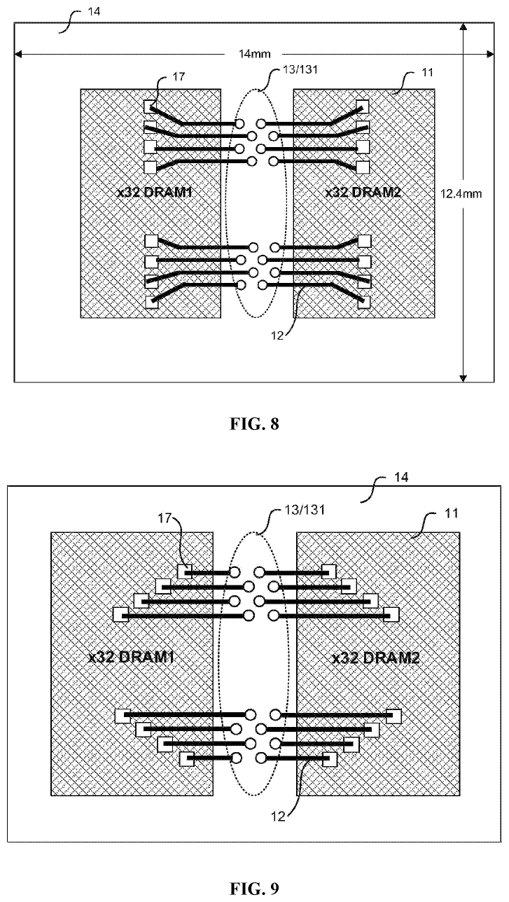

As shown in FIGS. 7 to 8, for example, the first connecting bodies 13 are distributed in the gap between the two chips 11; the bonding pads 17 are located in the middle region of the chip and are arranged in the parallel direction of the two chips 11; thus, the length of the first redistribution layer 12 is shortened.

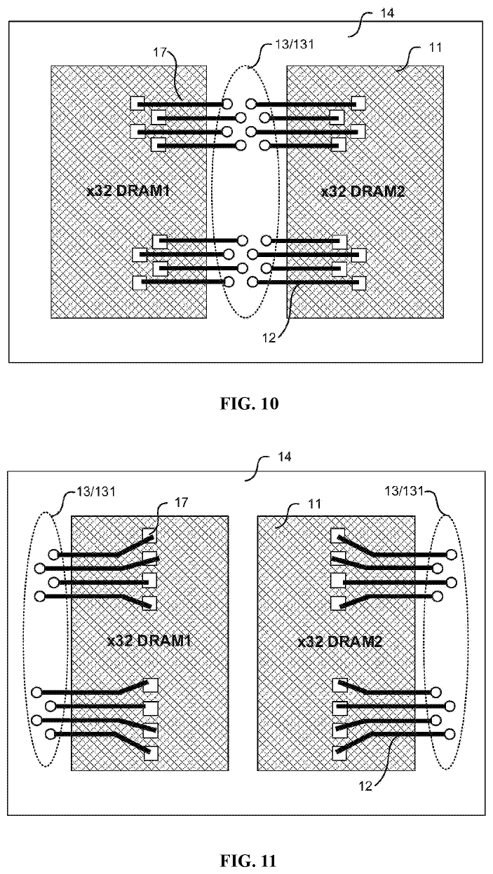

Illustratively, as shown in FIG. 9, the first connecting bodies 13 are distributed in the gap between the two chips 11; the bonding pads 17 are located in the middle region of the chips, gradually approaching the first connecting body from inside to outside along the parallel direction of the two chips 11, and gradually shortening the length of the first redistribution layer 12.

Illustratively, as shown in FIG. 10, the first connecting bodies 13 are distributed in the gap between the two chips 11; the bond pads 17 are located in the middle region of the die, and are arranged in a parallel direction along the two dies 11 as a whole, the bond pads 17 are not aligned, and the length of the first redistribution layer 12 is also shortened.

Illustratively, as shown in FIG. 11, the first connecting bodies 13 are distributed outside the chip 11; the bonding pads 17 are located in the middle region of the chip and are arranged in the parallel direction of the two chips 11; thus, the length of the first redistribution layer 12 is shortened.

Taking the pre-packages shown in FIG. 7-11 as an example, each pre-package includes two 32-bit Dynamic Random Access Memories (DRAMs), and the number of bonding pads 17, the number of first redistribution layers 12, and the number of first connectors 13 (i.e. first conductor pillars 131) disposed on the active surface of the chip 11 are all equal, and about 400 needs to be disposed; the diameter of the first conductor pillar 131 is 25 μm or more and the pitch is 40 μm or more; the minimum line width/pitch of the first re-wiring layer 12 is 5 μm.

It can be appreciated that FIG. 7-11 only exemplarily illustrate the distribution positions of the bonding pads 17 on the active surface side of the chip 11 and the number of the bonding pads 17 is 8, but do not constitute a limitation of the stack package provided by the embodiments of the present disclosure. In other embodiments, the distribution position and the number of the bonding pads may be flexibly set according to the requirements of the stacked package, which is not limited herein.

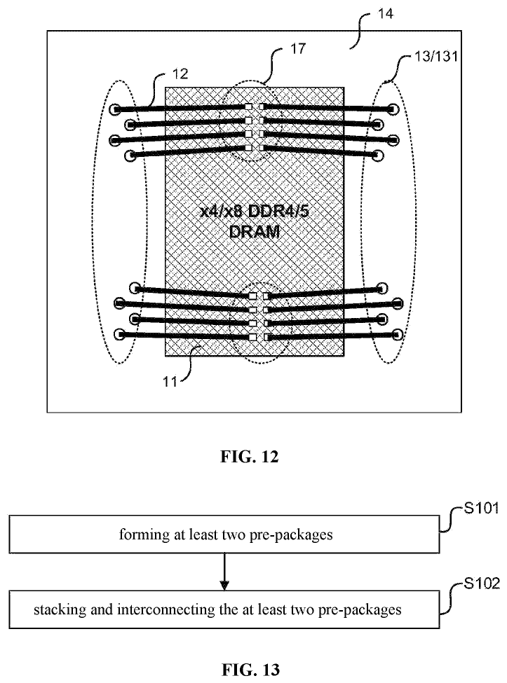

Illustratively, as shown in FIG. 12, a schematic structural diagram of yet another second pre-package is provided according to an embodiment of the disclosure. Referring to FIG. 12, the second pre-package includes a chip 11, and first connectors 13 are disposed at opposite sides of the chip 11; on one side of the active surface of the chip 11, 16 bonding pads 17 are provided, the bonding pads 17 being arranged in two columns along a direction parallel to the side; the bond pad 17 and the first connection body 13 are electrically connected through the first redistribution layer 12. The chip 11 is a double rate dynamic random access memory (DDR DRAM), the number of bonding pads 17 disposed on the active surface of the chip 11, the number of first redistribution layers 12, and the number of first connectors 13 (i.e., first conductor pillars 131) are all equal, 400 pre-packages of the bottommost layer in the stacked package are required to be disposed, and 100 pre-packages of the non-bottommost layer are required to be disposed; the diameter of the first conductor pillar 131 is 25 μm or more and the pitch is 40 μm or more; the minimum line width/pitch of the first re-wiring layer 12 is 5 μm.

In some embodiments, the chip includes at least one of a memory chip, a computing chip, a communication chip, a sensing chip, and an energy chip.

7-11, the chips 11 in the pre-package are two Dynamic Random Access Memories (DRAMs); as shown in FIG. 12, the chip 11 in the pre-package is a double rate dynamic random access memory (DDR DRAM); the embodiment of the disclosure is not limited to the type, the number, the capacity and the like of the packaged chips, and is applicable to all chips in the technical field.

In some embodiments, as shown in FIG. 1-2, the first connectors in two adjacent pre-packages are disposed in a consistent position.

As shown in FIG. 1-2, the first connectors 13 of two adjacent pre-packages 10 are arranged in a consistent position in the stacking interconnection direction, and are arranged in a gap between two chips 11, so that the two pre-packages 10 can be interconnected through the respective first redistribution layers 12 and the first connectors 13 therebetween; compared with the scheme that the arrangement positions of the first connection bodies 13 in the adjacent two pre-packages 10 are not consistent, the length of the first re-wiring layer 12 is further shortened, and therefore the electrical performance is improved.

On the basis of the foregoing embodiments, the embodiments of the present disclosure further provide a method for manufacturing a fan-out stack package, which is used for manufacturing any of the fan-out stack packages, and has corresponding beneficial effects, and in order to avoid repeated descriptions, the description is omitted here.

FIG. 13 is a flow chart illustrating a method for manufacturing a fan-out stack package according to an embodiment of the disclosure. Referring to FIG. 13, the method for manufacturing the fan-out stack package includes:
s101, forming at least two pre-packages.

Wherein, in connection with FIG. 1-2, each pre-package 10 comprises a chip 11, a first redistribution layer 12 and a first connection 13; in the stacked interconnection direction, the first redistribution layer 12 is located on the active surface side of the chip 11, and the first connecting body 13 and the chip 11 are located on the same side of the first redistribution layer 12; in the first preset direction X, the first connection body 13 is located on at least one edge side of the chip 11, and the first connection body 13 is electrically connected to the first redistribution layer 12.

The chip 11 includes, but is not limited to, a memory chip, a computing chip, a sensing chip, a communication chip, a sensing chip, and an energy chip. The first re-wiring layer 12 is prepared by electroplating or deposition process, and the material of the first re-wiring layer 12 may be at least one of copper, aluminum, silver, gold, and titanium. The first connecting body 13 may be provided as a metal pillar or a metal block formed of a metal material, such as a copper pillar, an aluminum pillar, a silver pillar, or the like, or may be a pillar formed of another conductive material. The first connecting body 13 and the first redistribution layer 12 may be made of the same material, or may be made of different materials.

S102, interconnecting the pre-package stack.

1-2, the active surface of one pre-package 10 of two adjacent pre-packages 10 is opposite to the passive surface of the other pre-package 10, and the first connection body 13 of one pre-package 10 is electrically connected with the first redistribution layer 12 of the other pre-package 10; the pre-package 10 comprises a first pre-package and at least one second pre-package; the first pre-package is positioned at the outermost side of the fan-out type stacked package and is used for being electrically connected with other components; in a first preset direction X, the length of the first pre-package is greater than the length of the second pre-package, and the first preset direction X is any direction perpendicular to the stacking interconnection direction. When the fan-out type stacked packaging body is integrally packaged, one side of the first pre-packaging body, which faces the second pre-packaging body, can be used as a substrate to provide a supporting effect for the encapsulation layer without connecting a substrate; the length of the first pre-package is equal to the length of the encapsulation layer in either direction perpendicular to the stack interconnect.

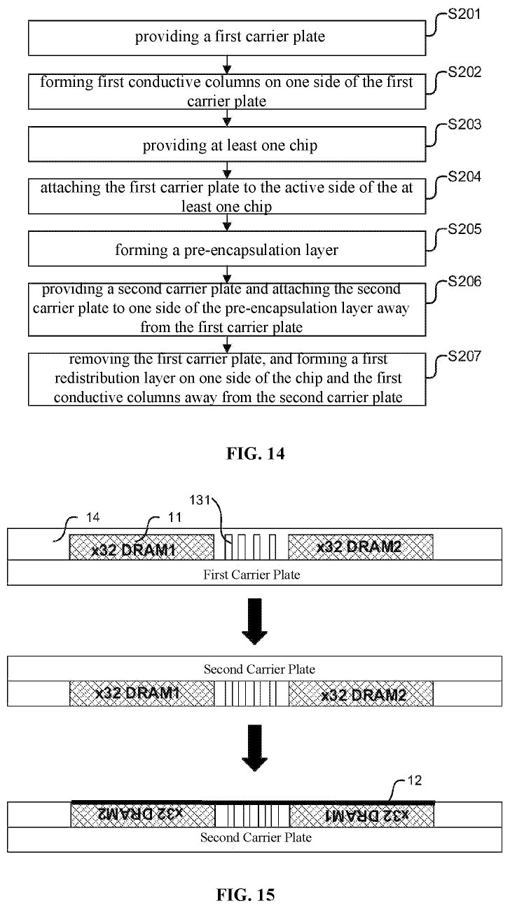

In some embodiments, as shown in FIG. 14-15, FIG. 14 is a schematic diagram of a refinement flow of “forming a pre-package” provided in the embodiments of the disclosure, and FIG. 15 is a schematic diagram of a structure corresponding to each step of “forming a pre-package”. Referring to FIGS. 14 and 15, “forming a pre-package” includes:

S201, providing a first carrier plate.

S202, forming a first conductor column on one side of the first carrier plate.

The first conductor pillar 131 may be prepared by an electroplating process, and may be prepared by any process known to those skilled in the art, which is not limited herein. The first conductor pillar 131 may be at least one of copper, aluminum, silver, gold, and titanium.

Illustratively, the first conductor pillar is prepared using an electroplating process, specifically: a photo-thermal conversion layer (Light To Heat Conversion Release Coating (LTHC) Ink), a polymer layer (e.g., polyimide), a seed layer (including at least one of copper and titanium), and a photoresist layer are sequentially deposited on a side of the first carrier, a first mask layer for patterning the photoresist layer is disposed over the photoresist layer to form a via hole through the photoresist layer, a first conductive pillar is formed in the via hole using an electroplating process, the photoresist layer is finally removed, and then the remaining seed layer is removed by etching.

S203, providing at least one chip.

Here, FIG. 15 illustrates only two chips 11, which are of a Dynamic Random Access Memory (DRAM) type, by way of example, but does not constitute a limitation of the fabrication method of the stack package provided in the embodiments of the present disclosure. In other embodiments, the number and types of chips can be flexibly set according to requirements, and are not limited herein.

S204, attaching the active surface of the chip to the first carrier plate.

Specifically, the chip 11 is attached to the first carrier by using an adhesive, and the active surface of the chip 11 is opposite to the first carrier; the chip 11 and the first conductor pillar 131 are located on the same side of the first carrier plate.

S205, forming a pre-encapsulation layer.

Specifically, the chip 11 and the first conductor pillar 131 are encapsulated with an insulating material (such as epoxy resin) to form the pre-encapsulation layer 14; the pre-encapsulation layer 14 coats the surfaces of the chip 11, the first conductor column 131 and the first carrier plate facing the chip 11 and the first conductor column 131; then, thinning the pre-encapsulation layer 14 by grinding until the surface of the first conductor column 131 on one side of the pre-encapsulation layer 14 away from the first carrier plate is exposed; in this way, the first conductor pillars 131 are filled and extend through the pre-encapsulation layer 14.

S206, providing a second carrier plate and attaching the second carrier plate to one side of the pre-encapsulation layer, which is away from the first carrier plate.

S207, removing the first carrier plate, and forming a first redistribution layer on one side of the chip and the first conductor column, which is away from the second carrier plate.

Wherein the first redistribution layer 12 is electrically connected to the chip and the first conductor pillars 131, i.e. the first conductor pillars 131 are electrically connected to the chip 11 through the first redistribution layer 12.

Specifically, when the first carrier plate is removed, the photo-thermal conversion layer deposited on the first carrier plate at the time of preparing the first conductor post 131 is removed together with the polymer layer and the adhesive used at the time of attaching the chip 11. After the first carrier is removed, the pre-package is turned upside down, and a first redistribution layer 12 is formed on one side of the active surface of the chip 11 by using an electroplating or deposition process, and the first redistribution layer 12 is electrically connected with the bonding pad of the chip 11 and the first conductor pillar 131.

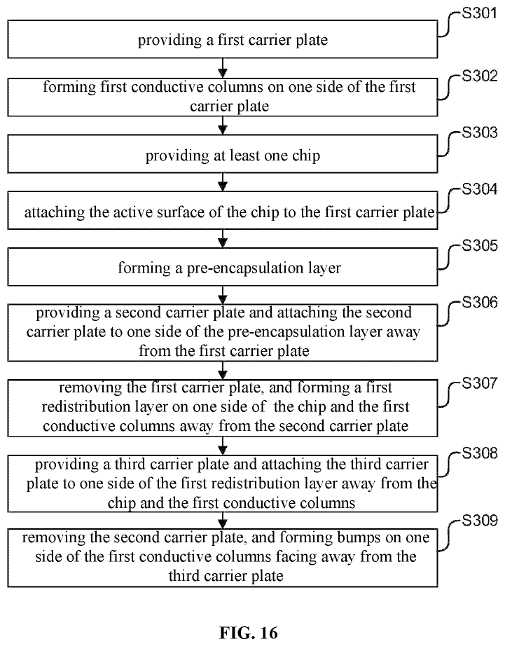

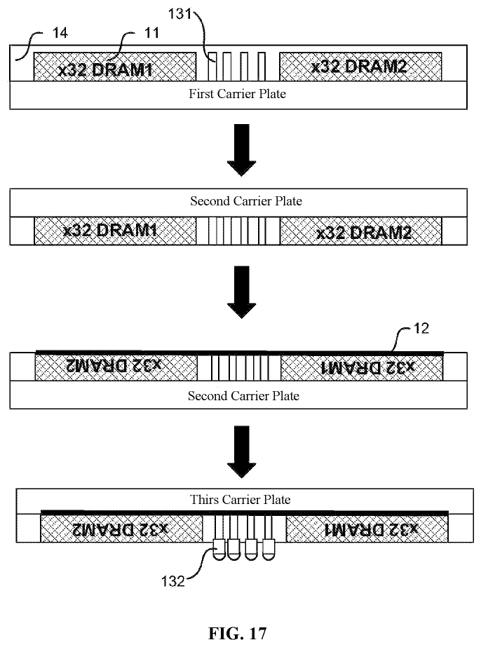

In some embodiments, as shown in FIG. 16-17, FIG. 16 is a detailed flow chart of “forming a second pre-package” provided in the embodiments of the present disclosure, and FIG. 17 is a structural schematic diagram corresponding to each step of “forming a second pre-package”. Referring to FIGS. 16 and 17, “forming the second pre-package” includes:
and S308, providing a third carrier plate and attaching the third carrier plate to one side of the first redistribution layer, which is away from the chip and the first conductor post.

Specifically, the third carrier is attached to the side of the first redistribution layer 12.

S309, removing the second carrier plate, and forming a metal bump on one side of the first conductor column, which is away from the third carrier plate.

The metal bump 132 is electrically connected to the first conductor pillar 131 and is exposed outside the surface of the pre-package layer 14.

Specifically, after the second carrier is removed, a metal bump 132 is formed on an end of the first conductor pillar 131 facing away from the first redistribution layer 12 by using an electroplating process; the metal bump 132 may be at least one of copper, aluminum, silver, gold, and titanium. Preferably, copper is used for the first conductor pillar 131 and the metal bump 132. A cap-shaped solder bump is formed at an end of the metal bump 132 facing away from the first conductor pillar 131, and solder is selected as the solder bump.

The pre-package formed by the method of the embodiment is suitable for the pre-package except the bottommost pre-package in the fan-out type stacked package; referring to FIG. 1-2, the resulting pre-packages are three pre-packages in the top and middle layers of a fan-out stack package.

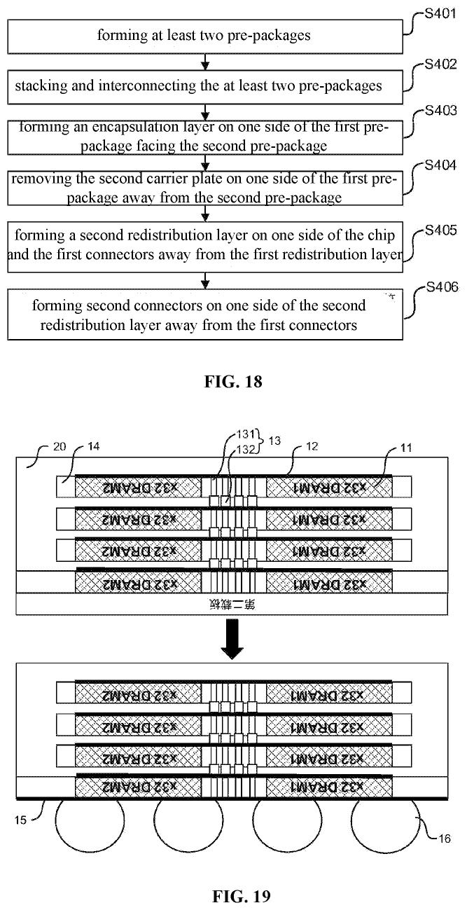

In some embodiments, as shown in FIG. 18-19, 18 is a flow chart of another method for manufacturing a fan-out stack package according to an embodiment of the present disclosure, and FIG. 19 is a schematic structural diagram corresponding to S403-S406 in the method for manufacturing a fan-out stack package shown in FIG. 18. Referring to FIG. 18-19, after interconnecting the pre-package stack, the method of making further comprises:
s403, forming an encapsulation layer on one side of the first pre-packaging body facing the second pre-packaging body.

Wherein the encapsulation layer 20 encapsulates the surface of the first pre-package facing the second pre-package and the second pre-package. The encapsulation layer 20 may be a prepreg, and the surface of the second pre-encapsulation body and the surface of the first pre-encapsulation body facing the second pre-encapsulation body may be coated with a prepreg, where the prepreg includes one or more of epoxy, polyethylene, polypropylene, polyolefin, polyamide, polyurethane, and the like. The encapsulation layer 20 may be made of a liquid or powder epoxy resin, and not only encapsulates all of the first pre-encapsulation body and the surface of the first pre-encapsulation body facing the second pre-encapsulation body, but also fills the gaps between all of the pre-encapsulation bodies.

In some embodiments, as shown in FIG. 18-19, the method of making further comprises:
s404, removing the second carrier plate on one side of the first pre-package body away from the second pre-package body.

And S405, forming a second redistribution layer on one side of the chip and the first conductor pillar away from the first redistribution layer.

Specifically, after the second carrier is removed, forming a second redistribution layer 15 on a side of the pre-package body away from the first redistribution layer 12 by using an electroplating or deposition process, where the second redistribution layer 15 is electrically connected to the first conductor pillar 131 of the pre-package body; the second redistribution layer 15 may be at least one of copper, aluminum, silver, gold, and titanium.

S406, forming second connectors on one side of the second redistribution layer away from the chip and the first connectors.

The second redistribution layer 15 is electrically connected to the first connection body 13 and the second connection body 16, and the second connection body 16 is used for externally connecting other components.

Specifically, the second connection body 16 is prepared using an electroplating process, and the second connection body 16 may be provided in one of a column shape, a block shape, or a ball shape, for example, the second connection body 16 is provided as a solder ball in FIG. 18; the second connector 16 is made of a conductive material including a metallic material (e.g., at least one of copper, aluminum, silver, gold, and titanium) and a conductive nonmetallic material. The number and arrangement of the second connectors 16 are flexibly set according to the external connection components, which is not limited herein.

On the basis of the implementation manner, the embodiment of the disclosure also provides electronic equipment. The electronic device includes: any of the fan-out stack packages described above has corresponding beneficial effects, and is not limited herein to avoid repetitive description.

The electronic devices include, but are not limited to, portable devices (e.g., laptops), mobile communication devices (e.g., smartphones and tablets), and computer servers.

It should be noted that in this document, relational terms such as “first” and “second” and the like are used solely to distinguish one entity or action from another entity or action without necessarily requiring or implying any actual such relationship or order between such entities or actions. Moreover, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. Without further limitation, an element defined by the phrase “comprising one . . . ” does not exclude the presence of other like elements in a process, method, article, or apparatus that comprises the element.

The foregoing is merely a specific embodiment of the disclosure to enable one skilled in the art to understand or practice the disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown and described herein but is to be accorded the widest scope consistent with the principles and novel features disclosed herein.

We claim:

1. A fan-out stack package, comprising: at least two pre-packages; each pre-package including at least a chip, a first redistribution layer and a first connector, each chip having an active side and a passive side, each respective pre-package having an active side corresponding to the active side of each the at least one chip in the respective pre-package, and a passive side opposite to the active side of the respective pre-package; wherein:
the at least two pre-packages are in stacked interconnection, the active surface of one pre-package body in two adjacent pre-packages is opposite to the passive surface of the other pre-package body, and the first connecting body of one pre-package body is electrically connected with the first redistribution layer of the other pre-package body;
wherein, in the stacking interconnection direction, the first redistribution layer is positioned on one side of the active surface of the chip, and the first connector and the chip are positioned on the same side of the first redistribution layer; in a first preset direction, at least some of the first connectors are positioned on at least one edge side of the chip, and the first connector is electrically connected with the chip through the first redistribution layer;
the pre-package comprises a first pre-package and at least one second pre-package; the first pre-package body is positioned at the outermost side of the fan-out type stacked package body for electrically connecting with external components; in a first preset direction, the length of the first pre-package is greater than that of the second pre-package, and the first preset direction is a direction perpendicular to the stacking interconnection direction.

2. The fan-out stack package of claim 1, wherein the pre-package further comprises: a pre-encapsulation layer, wherein the pre-encapsulation layer encapsulates the chip and the first connector; the first connector comprises a first conductor post;
the first conductor column is filled and penetrates through the pre-encapsulation layer and is connected with a first redistribution layer of the pre-packaging body.

3. The fan-out stack package of claim 2, wherein the first connector of the second pre-package further comprises a metal bump;
the metal bump is electrically connected with the first conductor post and is exposed outside the surface of the pre-encapsulation layer; the metal bump is electrically connected with the first redistribution layer of the adjacent pre-package.

4. The fan-out stack package of claim 2, wherein the first pre-package further comprises a second redistribution layer and a second connector;
The second redistribution layer is located the chip with the first conductor post deviates from one side of first redistribution layer, the second connector is located the second redistribution layer deviates from the chip with one side of first conductor post, the second redistribution layer with first conductor post with the second connector electricity is connected, the second connector is used for external connection other components and parts.

5. The fan-out stack package of claim 4, in which the second connector is provided as at least one of a second conductor post and a solder ball.

6. The fan-out stack package of claim 1, further comprising: the encapsulation layer is formed by a encapsulation layer,
the encapsulation layer is positioned on one side of the first pre-packaging body facing the second pre-packaging body, and the encapsulation layer coats the surface of the first pre-packaging body facing the second pre-packaging body and the second pre-packaging body.

7. The fan-out stack package of claim 1, wherein the pre-package further comprises: a bond pad;
the bonding pads are located on one side of the active surface of the chip, the bonding pads are distributed in the area, close to the first connecting body, of the chip, and the bonding pads are electrically connected with the first connecting body through the first redistribution layer.

8. The fan-out stack package of claim 1, in which the chip comprises at least one of a memory chip, a computing chip, a communication chip, a sense chip, and an energy chip.

9. The fan-out stack package according to claim 1, wherein the first connectors in two adjacent pre-packages are arranged at identical positions.

10. A method of manufacturing a fan-out stack package, comprising:
forming at least two pre-packages; the pre-package body at least comprises a chip, a first redistribution layer and a first connecting body;
interconnecting the pre-packages in a stacked manner, wherein the active surface of one pre-package body of two adjacent pre-packages is opposite to the passive surface of the other pre-package body, and the first connecting body of one pre-package body is electrically connected with the first redistribution layer of the other pre-package body;
wherein, in the stacking interconnection direction, the first redistribution layer is positioned on one side of the active surface of the chip, and the first connector and the chip are positioned on the same side of the first redistribution layer; in a first preset direction, at least some of the first connectors are positioned on at least one edge side of the chip, and the first connector is electrically connected with the chip through the first redistribution layer;
the pre-package comprises a first pre-package and at least one second pre-package; the first pre-package body is positioned at the outermost side of the fan-out type stacked package body and is used for being electrically connected with other components; in a first preset direction, the length of the first pre-package is greater than that of the second pre-package, and the first preset direction is any direction perpendicular to the stacking interconnection direction.

11. The method of manufacturing of claim 10, wherein forming the pre-package comprises:
providing a first carrier plate;
forming a first conductor column on one side of the first carrier plate;
providing at least one chip;
attaching the active surface of the chip to the first carrier plate; the chip and the first conductor post are positioned on the same side of the first carrier plate;
forming a pre-encapsulation layer, wherein the pre-encapsulation layer coats the surfaces of the chip, the first conductor column and the first carrier plate, which face the chip and the first conductor column, and the first conductor column is filled and penetrates through the pre-encapsulation layer;
providing a second carrier plate and attaching the second carrier plate to one side of the pre-encapsulation layer, which is away from the first carrier plate; and
removing the first carrier plate, and forming a first redistribution layer on one side of the chip and the first conductor column, which is away from the second carrier plate, wherein the first redistribution layer is electrically connected with the chip and the first conductor column.

12. The method of manufacturing of claim 11, wherein forming the second pre-package further comprises:
providing a third carrier plate and attaching the third carrier plate to one side of the first redistribution layer, which is away from the chip and the first conductor column; and
removing the second carrier plate, and forming a metal bump on one side of the first conductor column, which is away from the third carrier plate, wherein the metal bump is electrically connected with the first conductor column and is exposed outside the surface of the pre-encapsulation layer.

13. The method of manufacturing of claim 12, wherein after interconnecting the pre-package stack, the method of manufacturing further comprises:
forming a encapsulation layer on one side of the first pre-packaging body facing the second pre-packaging body; the encapsulation layer coats the surface of the first pre-packaging body facing the second pre-packaging body.

14. The method of manufacturing according to claim 13, further comprising:
removing a second carrier plate on one side of the first pre-package body away from the second pre-package body;
forming a second redistribution layer on one side of the chip and the first conductor pillar away from the first redistribution layer;
forming a second connector on one side of the second redistribution layer away from the chip and the first conductor pillar;
the second redistribution layer is electrically connected with the first connector and the second connector, and the second connector is used for externally connecting other components.

15. An electronic device, comprising: the fan-out stack package of claim 1.
